(19) United States
(12) Patent Application Publication
(10) Pub. No.: US 2012/0129099 A1
(43) Pub. Date: May 24, 2012

(54) Method For Producing Pigments

(75) Inventors: Frank Linke, Koln (DE); Ulrich Feldhues, Bergisch-Gladbach (DE)

(73) Assignee: LANXESS DEUTSCHLAND GMBH, Leverkusen (DE)

(21) Appl. No.: 13/382,553

(22) PCT Filed: Jul. 5, 2010
(86) PCT No.: PCT/EP2010/059543

§ 371 Date: Feb. 2, 2012

(30) Foreign Application Priority Data
Jul. 8, 2009 (EP) 09164931

(51) Int. Cl. C07F 15/04; G03F 7/004; C08K 5/3462

(52) U.S. Cl. 430/281.1; 544/225; 106/480

(57) ABSTRACT

Process for preparing pigments of the formula (I)

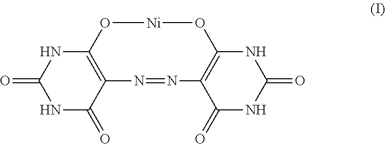

or tautomeric structures thereof and their hydrates, containing melamine or melamine derivatives as guest(s), characterized in that the azobarbituric mono-salt of the formula (II) is reacted with a nickel compound and melamine or a melamine derivative in the presence of the free azobarbituric acid of the formula (III),

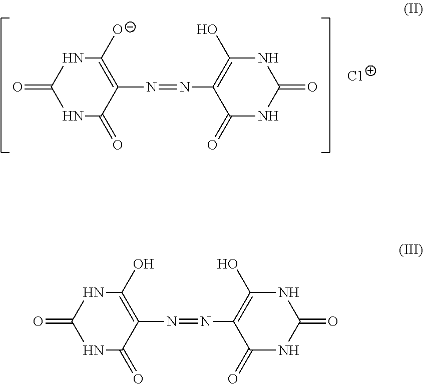

the cation C1^{⊕} is any desired univalent cation or the fraction of any desired multivalent cation that corresponds to a positive charge of one, except for H⁺.

### CROSS REFERENCE TO RELATED PATENT APPLICATIONS

The present patent application claims the right of priority under 35 U.S.C. §119 (a)-(d) and 35 U.S.C. §365 of International Application No. PCT/EP2010/59543, filed Jul. 5, 2011, which was published in German as International Patent Publication No. WO 2011/003851 A1 on Jan. 13, 2011, which is entitled to the right of priority of European Patent Application No. EP 09164931.9 filed on Jul. 8, 2009.

The invention relates to a process for preparing melamine-hosting pigments, their hydrates, and the use of these process products.

It is known that in the preparation of azobarbituric acid Ni complexes containing melamine as guest, and their hydrates, there may be severe fluctuations in product properties. Especially under production conditions on the industrial scale, particularly in a batch process, certain parameters of the resulting material, such as the BET specific surface area, are subject to more or less severe fluctuations. This is of course a disadvantage—what the consumers of these products want is consistent product quality.

A certain standardization in product quality (reproducibility) is possible by means of a heat-treatment step, as described for example in EP-A1-0994162 or DE 10328999 A1. Particularly on the industrial scale, of course, this implies an additional, time-consuming step and hence an increase in manufacturing costs.

EP-A 1 612 246 describes likewise great quality fluctuations in the batch production of the azobarbituric acid Ni complex in accordance with the prior art, and proposes avoiding this disadvantage by means of specific additions at the synthesis stage. This, admittedly, necessitates additional logistical effort and expense, and affects the composition of the product, since these additions can contaminate the end product.

EP-A-1987045 describes a process in which a mixture of the mono- and di-cation complexes of azobarbituric acid known from EP-A-1068992 is reacted with a nickel compound and melamine. The reproducibility of this process is already improved. The products obtained according to this process still, however, show deficits in quality, in particular with respect to particle size, particle-size distribution and transparency.

Surprisingly it has now been found that the quality of the azobarbituric acid Ni complex containing melamine as a guest can be improved significantly by reacting a mixture of the mono-cation complex and the free azobarbituric acid, in particular a mixture of the mono-potassium complex of azobarbituric acid and the free azobarbituric acid with melamine and with a nickel compound. The compound of the formula (I) containing melamine as guest can be prepared, even industrially, by the process of the invention, reproducibly, with a directable surface area, a very high colour strength, a very narrow particle-size distribution and a very high transparency. This is particularly advantageous for the use of pigments prepared in this way for colour fillers for liquid-crystal displays.

The invention accordingly provides a process for preparing pigments of the formula (I)

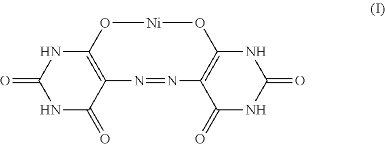

or tautomeric structures thereof and their hydrates, containing melamine or melamine derivatives as guest(s), which is characterized in that the azobarbituric acid mono-salt of the formula (II) is reacted with a nickel compound and melamine or a melamine derivative in the presence of the free azobarbituric acid of the formula (III),

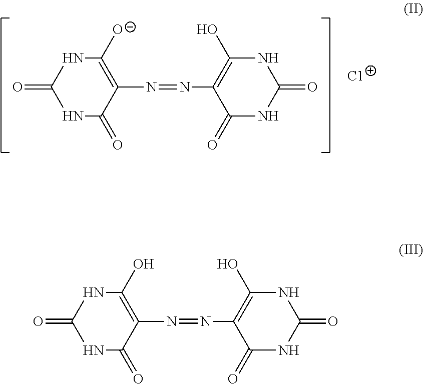

where the cation C1^{⊕} is any desired univalent cation or the fraction of any desired multivalent cation that corresponds to a positive charge of one, except for H⁺.

Preferred melamine or melamine derivatives are in particular those of the formula (IV)

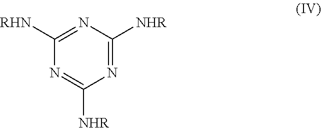

in which

R is hydrogen or C₁-C₄-alkyl which is optionally substituted with OH groups, very preferably in which

R is hydrogen.

The compound (I) may contain not only melamine but also, where appropriate, further guest compounds, of the kind described for example in EP 0994162 (page 5, line 40 to page 7, line 58 therein). The compound (I) preferably contains 1.5 to 2.2 units of melamine or melamine derivative, in particular 1.9 to 2.1 units, as guest.

With particular preference the cation C1^{⊕} in the formula (II) is an alkali metal cation, especially Li, Na or K cation, ½ alkaline earth metal cation, especially ½ Mg, ½ Ca cation, ⅓ Al cation, or ammonium cation unsubstituted or substituted by any desired radicals, especially unsubstituted ammonium cation. With particular preference, C1^{⊕} is K⁺.

Preferred mono-salts of the formula (II) are monohydrates.

The fraction of the formula (III) is preferably produced starting from the mono-salt (II) by adding an acidic compound, in particular by adding an organic or inorganic acid or acidic salts, in the form for example of a solution, directly from the monocation complex of azobarbituric acid. With particular preference it takes place by addition of hydrochloric acid, sulphuric acid or phosphoric acid, in particular in the form of a solution. Very preferably the mixture is produced by addition of a dilute aqueous hydrochloric acid solution of the mono-salt (II).

Preference is given to the process of the invention in which, relative to the sum of the formulae (II) and (III), the fraction of the free azobarbituric acid of the formula III is 5-80%, more particularly 10-50%, very preferably 10-30%, by weight.

Nickel compounds contemplated include more particularly nickel formate, nickel nitrate, nickel sulphate, nickel chloride and/or nickel acetate; nickel chloride is particularly preferred.

The nickel compound is used preferably in a molar ratio to the sum of the two compounds of the formulae (II) and (III) of 95% to 120%, more particularly of 100% to 110%.

The process of the invention takes place preferably at a temperature of 60 to 100° C., more particularly 70-90° C.

The reaction according to the invention takes place preferably in a solvent, a water-containing solvent system being used more particularly. Further solvent constituents contemplated include organic solvents. Preference in this case is given to C₁-C₄ alcohols.

Particularly preferred is an aqueous solvent, having more particularly a water fraction of more than 50% by weight, preferably of 80-100% by weight. With very particular preference the process of the invention takes place in an aqueous solvent system without addition of organic solvents.

In one preferred embodiment of the process of the invention, first melamine or the melamine derivative is added to the compounds of the formulae (II) and (III), and thereafter the nickel compound.

The pH during the reaction with the nickel compound and with melamine is preferably less than pH 7, more preferably less than pH 3, more particularly at pH 1 to 2.

The reaction to compound (I) is preferably completed after adding the nickel compound by subsequent stirring for one to five hours, in particular at temperatures from 60-100° C.

The pigments obtained by the process of the invention can of course be aftertreated by a heat-treatment step, of the kind described for example in EP A1-0994162 or DE 10328999 A1. Advantageously, however, this aftertreatment may also be omitted entirely.

The suspension preferably obtained in the preparation is preferably filtered, and the resultant presscake can be dried, where appropriate after washing with water.

Suitable in this context on the one hand are typical drying methods such as paddle drying, etc. With drying methods of this kind and with subsequent, conventional grinding of the pigment, pulverulent pigments are obtained.

The presscake is preferably spray-dried as an aqueous slurry. The slurry for spraying possesses a solids fraction preferably of 10% to 40% by weight, in particular 15% to 30% by weight.

The dried pigments are preferably present in the form of hydrates, depending on the drying conditions.

Preferred pigments prepared by the process of the invention possess a BET surface area of >100 m²/g, preferably from 130 to 210 m²/g, in particular from 150 to 190 m²/g, determined in accordance with DIN 66131.

The invention additionally provides a process for producing pigment preparations in which at least one inventively prepared pigment and at least one dispersant are mixed. Such pigment preparations are also inventive. These pigment preparations serve preferably for incorporation into aqueous systems.

In respect of suitable dispersants, reference may be made to the prior art, particularly EP-A1-0994164, page 8, line 56 to page 11, line 23, whose disclosure content is part of this application.

The invention further provides a photoresist which comprises at least one photocurable monomer and at least one photoinitiator and at least one pigment prepared by the process of the invention. The invention further provides colour filters and liquid-crystal displays produced from them, comprising at least one pigment prepared by the process of the invention.

In the case of the production of the colour filters for liquid-crystal displays, the inventively prepared pigment, preferably in an organic solvent, where appropriate with addition of a binder resin and/or dispersant, is ground, then processed to a photoresist with addition of photocurable monomers, photoreaction initiators and, where appropriate, further binder and/or solvent, and this photoresist is then applied to a suitable substrate, generally a glass plate, by means of suitable coating techniques such as roller, spray, spin, dip or air-knife coating, for example, and the coated plate is exposed using a photomask, then cured and developed to give the completed coloured filter.

The invention additionally provides, preferably, for the use of the inventively prepared pigment as a pigment for colour filters in liquid-crystal displays.

The inventively prepared compound (I) containing melamine as guest, or pigment preparations thereof, are outstandingly suitable, moreover, for all pigment applications.

They are suitable, for example, for pigmenting varnishes of all kinds, for the production of printing colours, colours or binder colours, for the mass coloration of synthetic, semisynthetic or natural macromolecular compounds, such as polyvinyl chloride, polystyrene, polyamide, polyethylene or polypropylene, for example. They can also be used for the spin-dyeing of natural, regenerated or artificial fibres, such as cellulose, polyester, polycarbonate, polyacrylonitrile or polyamide fibres, and also for the printing of textiles and paper. These pigments provide finely divided, stable, aqueous pigmentation of emulsion and paint colours which are useful for paper coloration, for the pigment printing of textiles, for laminate printing or for the spin-dyeing of viscose, by grinding or kneading in the presence of nonionic, anionic or cationic surfactants. The pigments prepared by the process of the invention are outstandingly suitable for inkjet applications and for colour filters for liquid-crystal displays.

### EXAMPLES

a) Synthesis

Monopotassium Salt

Starting material for the process of the invention was Example 1 of EP-A 1 086 992, i.e. the α-form of azobarbituric acid monopotassium salt ×1 H₂O, which is described below.

136 g of aminoguanidine bicarbonate were introduced into 810 g of distilled water and dissolved therein with 280 g of hydrochloric acid (30% strength). The solution was thereafter cooled down to about −10° C. with 780 g of ice and subsequently admixed with 232 g of 37% strength potassium nitrite solution in water to about 15° C. This was followed by 15 minutes of stirring at about 15° C., after which 2.0 g of amidosulphuric acid were added. Then 269 g of barbituric acid were introduced, and the mixture was subsequently heated to 55° C. and stirred for 2 hours. The mixture was then adjusted to a pH of 2.5 using aqueous potassium hydroxide solution and stirred for 30 minutes. Thereafter the pH was adjusted to 4.8 using aqueous potassium hydroxide solution and stirring was continued for 30 minutes. Subsequently the batch was heated to 80° C. and subsequently stirred at a pH of 4.8 for 3 hours. Thereafter the product was isolated on a suction filter and washed until electrolyte-free.

Non-Inventive, Synthesis Comparative Example N

425 g of water-moist paste of the α-form of azobarbituric acid monopotassium salt ×1 H₂O, described above, with a solids content of 40%, corresponding to 170 g dry (0.5 mol), were stirred in 5000 ml of distilled water with a laboratory stirrer and heated to 95° C. 1060 g of aqueous 6.5% strength nickel chloride solution were added over the course of 30 minutes. Thereafter 126 g of melamine (1 mol) were added and stirring was continued at 95° C. for 1.5 hours. The pH was then adjusted to 5.5 using potassium hydroxide solution. The product was subsequently isolated on a suction filter, washed until electrolyte-free, dried in a vacuum drying cabinet at 80° C. and ground.

The specific surface area was determined in accordance with DIN 66131: Determination of the specific surface area of solids by gas adsorption by the method of Brunauer, Emmett and Teller (B.E.T.).

The product had a BET surface area of 83 m²/g. The product exhibited very nonuniform, partly platelet-shaped, partly distinctly needle-shaped particles under the electron microscope.

Repeat syntheses showed considerable variation (57 m²/g-92 m²/g).

### Inventive Synthesis Example 1

425 g of water-moist paste of the above-prepared a-form of azobarbituric acid monopotassium salt ×1 H₂O with a solids content of 40%, corresponding to 170 g dry (0.5 mol), were stirred in 5000 ml of distilled water with a laboratory stirrer and heated to 80° C.

12 g of 30% strength hydrochloric acid were added dropwise (0.1 mol; 20% based on azobarbituric monopotassium salt employed) and the mixture was stirred for 30 minutes. This gave a mixture in the molar proportion of 80 parts of monopotassium salt and 20 parts of free azobarbituric acid. 126 g of melamine (1 mol) were added. 1060 g of aqueous 6.5% strength nickel chloride solution were added over the course of 30 minutes and thereafter stirring was continued at 80° C. for 3 hours. The pH was then adjusted to 5.5 using potassium hydroxide solution. The product was subsequently isolated on a suction filter, washed until electrolyte-free, dried in a vacuum drying cabinet at 80° C. and ground.

The specific surface area was determined in accordance with DIN 66131: Determination of the specific surface area of solids by gas adsorption by the method of Brunauer, Emmett and Teller

The product had a BET surface area of 170 m²/g. The product exhibited very uniform, small, almost platelet-shaped particles under the electron microscope.

Repeat syntheses showed minor variation (161 m²/g-178 m²/g).

### Inventive Synthesis Example 2

Reaction as in Example 1, but 6 g of 30% strength hydrochloric acid were added dropwise (0.05 mol; 10% based on azobarbituric monopotassium salt employed). This gave a mixture in the molar proportion of 90 parts of monopotassium salt and 10 parts of free azobarbituric acid.

The product had a BET surface area of 166 m²/g. The product exhibited very uniform, small, almost platelet-shaped particles under the electron microscope.

Repeat syntheses showed minor variation (158 m²/g-171 m²/g).

### Inventive Synthesis Example 3

Reaction as in Example 1, but 18 g of 30% strength hydrochloric acid were added dropwise (0.15 mol; 30% based on azobarbituric monopotassium salt employed). This gave a mixture in the molar proportion of 70 parts of monopotassium salt and 30 parts of free azobarbituric acid.

The product had a BET surface area of 178 m²/g. The product exhibited very uniform, small, short-needle-like particles under the electron microscope.

Repeat syntheses showed minor variation (165 m²/g-186 m²/g).

### USE EXAMPLES

Production of a yellow preparation and use for producing a yellow colour filter

### Use Example 1 (Inventive)

Pigment used: pigment from Inventive Synthesis Example 1

In a stirred vessel, 774 parts by weight of methoxybutyl acetate and 286 parts by weight of a 21% strength solution of an alkaline-soluble copolymer (binder resin) based on benzyl methacrylate (70p)/2-hydroxyethyl methacrylate (15p)/methacrylic acid (15p), molar weight approximately 25 000 g/mol, in methoxypropyl acetate were mixed homogeneously. This gave a “preparation”.

Subsequently, 100 parts by weight of pigment from Example 1, dried beforehand at 80° C. to a residual moisture content of less than 1% by weight, were introduced homogeneously into the preparation.

The pigment suspension was ground in a horizontal, closed bead mill, using yttrium-stabilized zirconium oxide beads (diameter 0.6 to 1.0 mm).

Production of a Photoresist

Introduced homogenously and with stirring into 1000 parts by weight of the resultant preparation were 34.5 parts by weight of trimethylolpropane triacrylate (monomeric reactive diluent) and 13.8 parts by weight of a photoreaction initiator based on benzophenone and N,N′-tetra-ethyl-4,4′-diaminobenzophenone in a ratio of 3/1 parts by weight.

This gave a UV-radiation-curable photoresist, which was applied to a transparent substrate and developed to form the colour filter.

For this purpose, the photoresist was spin-coated onto a section of cleaned borosilicate glass (Corning® 7059, Owens Corning Corp.) measuring 300×350 mm and dried in an oven at 110° C. for 5 minutes under clean conditions, to form a film with a thickness of approximately 1.5-2 μm.

The film was subsequently exposed, after cooling, by means of a negative mask to produce the desired strip image pattern, and by means of an ultra-high-pressure mercury vapour lamp, at a UV dose of 200 mJ/cm², and then developed at room temperature using 0.06% strength aqueous potassium hydroxide solution, cleaned with fully demineralized water and dried. This was followed by a 30-minute aftercure at 235° C. in an oven under clean conditions.

The yellow inventive colour filter 1 thus obtained possessed a very clearly improved spectral transparency as compared with the noninventive colour filter N produced in accordance with Use Example N. The colour purity and brilliance of the colour filter 1 is excellent.

### Use Example N (NOT INVENTIVE)

Pigment used: pigment from noninventive, Comparative Synthesis Example N

In the same way as for Use Example 1, 100 parts by weight of pigment from noninventive, Comparative Example N, dried beforehand at 80° C. to a residual moisture content of less than 1% by weight, were introduced homogeneously into the preparation from Use Example 1.

The pigment suspension obtained was ground in a horizontal, closed bead mill, using yttrium-stabilized zirconium oxide beads, in the same way as in Use Example 1.

The production of the photoresist likewise took place as for Use Example 1.

### Use Example 2 (Inventive)

Pigment used: pigment from inventive Synthesis Example 2

In the same way as for Use Example 1, 100 parts by weight of pigment from Synthesis Example 2, dried beforehand at 80° C. to a residual moisture content of less than 1% by weight, were introduced homogeneously into the preparation from Use Example 1.

The pigment suspension obtained was ground in a horizontal, closed bead mill, using yttrium-stabilized zirconium oxide beads, in the same way as in Use Example 1.

The production of the photoresist likewise took place as for Use Example 1.

The yellow inventive colour filter 2 thus obtained possessed a very clearly improved spectral transparency as compared with the noninventive colour filter N produced in accordance with Use Example N. The colour purity and brilliance of the colour filter 2 is excellent.

### Use Example 3 (Inventive)

Pigment used: pigment from inventive Synthesis Example 3

In the same way as for Use Example 1, 100 parts by weight of pigment from Synthesis Example 3, dried beforehand at 80° C. to a residual moisture content of less than 1% by weight, were introduced homogeneously into the preparation from Use Example 1.

The pigment suspension obtained was ground in a horizontal, closed bead mill, using yttrium-stabilized zirconium oxide beads, in the same way as in Use Example 1.

The production of the photoresist likewise took place as for Use Example 1.

The yellow inventive-colour filter 3 thus obtained possessed a very clearly improved spear transparency as compared with the noninventive colour filter N produced in accordance with Use Example N. The colour purity and brilliance of the colour filter 3 is excellent.

What is claimed is:

1. Process for preparing pigments of the formula (I) 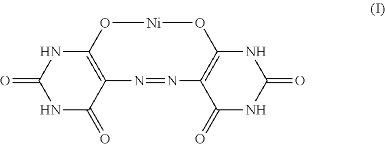
or tautomeric structures thereof and their hydrates, containing melamine or melamine derivatives as guest(s), wherein the azobarbituric mono-salt of the formula (II) is reacted with a nickel compound and melamine or a melamine derivative in the presence of the free azobarbituric acid of the formula (III), 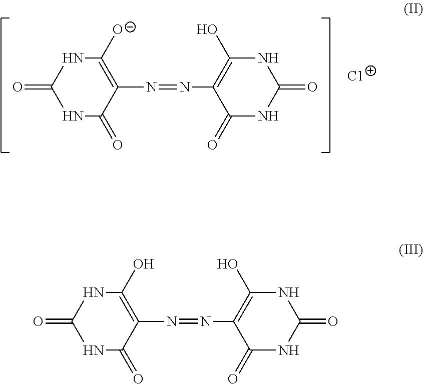
where the cation C1^{⊕} is any desired univalent cation or the fraction of any desired multivalent cation that corresponds to a positive charge of one, except for H⁺.

2. Process according to claim 1, wherein the cation C1^{⊕} in the formula (II) is an alkali metal cation, ½ alkaline earth metal cation, is ⅓ Al cation or is unsubstituted or substituted ammonium cation.

3. Process according to claim 1 wherein the cation C1^{⊕} in the formula (II) is Li, Na, K-cation, ½ Mg, ½ Ca cation, ⅓ Al cation or an unsubstituted ammonium cation.

4. Process according to claim 1, wherein the cation C1^{⊕} is K®.

5. Process according to claim 1, wherein, based on the sum of both compounds of the formulae (II) and (III), the fraction of the free azobarbituric acid of the formula (III) is 5 -80% by weight.

6. Process according to claim 1, wherein the fraction of the formula (III) is produced starting from the mono-salt II by adding an acidic compound.

7. Process according to claim 1, wherein first melamine or a melamine derivative, and then the nickel compound are added to the compounds of the formulae (II) and (III).

8. Process according to claim 1, wherein the pigments prepared possess a BET surface area, determined in accordance with DIN 66131, of greater than 100 m²/g.

9. Process according to claim 1, wherein the compounds of the formulae (II) and (III) are reacted at pH<7 with melamine and a nickel salt.

10. Pigments obtainable by the process according to claim 1.

11. A process for producing printing colours, distemper colours or binder colours, for the mass coloration of synthetic, semisynthetic or natural macromolelcular compounds, especially polyvinyl chloride, polystyrene, polyamide, polyethylene or polypropylene, and for the spin-dyeing of natural, regenerated or artificial fibres, such as cellulose, polyester, polycarbonate, polyacrylonitrile or polyamide fibres, and also for the printing of textiles and paper by applying the pigments according to claim 10.

12. A process for the production of laminates, as pigment for the production of photoresists, as pigment for the production of colour filters in liquid-crystal displays or as pigment for inkjet applications by applying the pigments according to claim 10 as pigment.

13. Pigment preparations comprising at least one pigment according to claim 10 and at least one dispersant.

14. Photoresist comprising at least one pigment according to claim 10, at least one photoinitiator and a photocurable monomer.

15. Colour filter comprising at least one pigment according to claim 10.
